(19) United States
(12) Patent Application Publication
(10) Pub. No.: US 2023/0077954 A1
(43) Pub. Date: Mar. 16, 2023

(54) ELECTRONIC DEVICE, METHOD OF MANUFACTURING AND MEASURING METHOD FOR ELECTRONIC DEVICE

(71) Applicant: Sumitomo Electric Industries, Ltd., Osaka (JP)

(72) Inventor: Kazutoshi NATSUME, Osaka-shi (JP)

(73) Assignee: Sumitomo Electric Industries, Ltd., Osaka (JP)

(21) Appl. No.: 17/880,273

(22) Filed: Aug. 3, 2022

(30) Foreign Application Priority Data
Sep. 10, 2021 (JP) 2021-148086

(51) Int. Cl. H01L 23/00; G01B 11/06; H01L 25/16; G01S 17/48

(52) U.S. Cl. CPC H01L 24/81; G01B 11/06; G01S 17/48; H01L 24/16; H01L 24/32; H01L 24/73; H01L 25/167; H01L 27/1469

(57) ABSTRACT

An electronic device includes a first chip, a second chip bonded to the first chip with a bump, a first metal pattern provided on a first surface that is a surface of the first chip facing the second chip, and a second metal pattern provided on a second surface that is a surface of the second chip facing the first chip. The first chip has a first transmission region. A transmittance for light of the first transmission region is higher than a transmittance of a region other than the first transmission region in the first chip. The first metal pattern and the second metal pattern overlap the first transmission region in a thickness direction of the first chip and the second chip. The second metal pattern is located outside the first metal pattern in a direction in which the first surface and the second surface extend.

### CROSS REFERENCE TO RELATED APPLICATIONS

This application claims priority based on Japanese Pat. Application No. 2021-148086 filed on Sep. 10, 2021, and the entire contents of the Japanese pat. application are incorporated herein by reference.

### TECHNICAL FIELD

The present disclosure relates to an electronic device, a method of manufacturing and a method of measuring an electronic device.

### BACKGROUND

An electronic device is formed by flip-chip bonding a chip to a substrate with bumps. There is a technique for evaluating a mounting state such as a gap by measuring capacitance (for example, JP2010-56429A).

### SUMMARY

An electronic device according to the present disclosure includes a first chip, a second chip bonded to the first chip with a bump; a first metal pattern provided on a first surface that is a surface of the first chip facing the second chip, and a second metal pattern provided on a second surface that is a surface of the second chip facing the first chip. The first chip has a first transmission region, a transmittance for light of the first transmission region is higher than a transmittance of a region other than the first transmission region in the first chip, the first metal pattern and the second metal pattern overlap the first transmission region in a thickness direction of the first chip and the second chip and the second metal pattern is located outside the first metal pattern in a direction in which the first surface and the second surface extend.

A method of manufacturing an electronic device according to the present disclosure is a method of manufacturing an electronic device having a first chip and a second chip. The first chip has a first transmission region, a transmittance for light of the first transmission region is higher than a transmittance of a region other than the first transmission region in the first chip, a first metal pattern is provided on a first surface that is a surface of the first chip facing the second chip, and a second metal pattern is provided on a second surface that is a surface of the second chip facing the first chip. The method includes bonding, with a bump, the first chip and the second chip arranged such that the first metal pattern and the second metal pattern overlap the first transmission region in a thickness direction of the first chip and the second chip, and such that the second metal pattern is located outside the first metal pattern in a direction in which the first surface and the second surface extend and after the bonding, making light incident on the first metal pattern and the second metal pattern through the first transmission region, and measuring a distance between the first chip and the second chip by using light reflected by the first metal pattern and light reflected by the second metal pattern.

A method of measuring an electronic device according to the present disclosure is a method of measuring an electronic device having a first chip and a second chip. The first chip and the second chip are bonded with a bump, wherein the first chip has a first transmission region, a transmittance for light of the first transmission region is higher than a transmittance of a region other than the first transmission region in the first chip, a first metal pattern is provided on a first surface that is a surface of the first chip facing the second chip, a second metal pattern is provided on a second surface that is a surface of the second chip facing the first chip, the first metal pattern and the second metal pattern overlap the first transmission region in a thickness direction of the first chip and the second chip, and the second metal pattern is located outside the first metal pattern in a direction in which the first surface and the second surface extend. The method includes making light incident on the first metal pattern and the second metal pattern through the first transmission region and measuring a distance between the first chip and the second chip by using light reflected by the first metal pattern and light reflected by the second metal pattern.

### BRIEF DESCRIPTION OF THE DRAWINGS

FIG. 1A is a plan view showing an electronic device according to a first embodiment.

FIG. 1B is a cross-sectional view taken along line A-A of FIG. 1A.

FIG. 2 is an enlarged view near the transmission region.

FIG. 3A is a cross-sectional view showing a method of manufacturing an electronic device.

FIG. 3B is a cross-sectional view showing a method of manufacturing an electronic device.

FIG. 3C is a cross-sectional view showing a method of manufacturing an electronic device.

FIG. 4A is a cross-sectional view showing a method of manufacturing an electronic device.

FIG. 4B is a cross-sectional view showing a method of manufacturing an electronic device.

FIG. 5A is a plan view showing an electronic device according to a second embodiment.

FIG. 5B is a cross-sectional view taken along line A-A of FIG. 5A.

FIG. 6A is a cross-sectional view showing a method of manufacturing an electronic device.

FIG. 6B is a cross-sectional view showing a method of manufacturing an electronic device.

### DETAILED DESCRIPTION

It has been difficult to measure the distance (gap) between two chips by a light-optical method after bonding the two chips by flip-chip bonding. It is therefore an object of the present invention to provide an electronic device capable of measuring a distance between chips, a method of manufacturing and a method of measuring an electronic device.

### Description of Embodiments of Present Disclosure

First, the contents of the embodiments of the present disclosure will be listed and explained.

(1) An electronic device according to an aspect of the present disclosure includes a first chip, a second chip bonded to the first chip with a bump, a first metal pattern provided on a first surface that is a surface of the first chip facing the second chip, and a second metal pattern provided on a second surface that is a surface of the second chip facing the first chip. The first chip has a first transmission region, a transmittance for light of the first transmission region is higher than a transmittance of a region other than the first transmission region in the first chip, the first metal pattern and the second metal pattern overlap the first transmission region in a thickness direction of the first chip and the second chip, and the second metal pattern is located outside the first metal pattern in a direction in which the first surface and the second surface extend. The distance between the first chip and the second chip can be measured by using the reflected light of the first metal pattern and the reflected light of the second metal pattern.

The second chip has a second transmission region, a transmittance for light of the second transmission region may be higher than a transmittance of a region other than the second transmission region in the second chip, the second transmission region may overlap the first transmission region in the thickness direction, and the first metal pattern and the second metal pattern may overlap the first transmission region and the second transmission region in the thickness direction of the first chip and the second chip. The distance between the first chip and the second chip may be measured by using the reflected light of the first metal pattern and the reflected light of the second metal pattern.

The electronic device may include a fourth metal pattern provided on a fourth surface that is a surface of the second chip opposite to the second surface. The fourth metal pattern may be located outside the first metal pattern and the second metal pattern in the direction in which the first surface and the second surface extend. The thickness of the second chip may be measured by using the reflected light of the second metal pattern and the reflected light of the fourth metal pattern.

The second chip may have a second substrate and a second electrode, the bump may be connected to the second electrode, the second transmission region may include the second substrate, and the second electrode may be provided in the region other than the second transmission region. The light transmitted through the second transmission region is reflected by the first metal pattern and the second metal pattern.

The first chip may have the first transmission region including multiple first transmission regions, and the first metal pattern including multiple first metal patterns, and the second chip may have the second metal pattern including multiple second metal patterns. By measuring the distance at multiple positions, the inclination between the first chip and the second chip can be measured.

The electronic device may include a third metal pattern provided on a third surface that is a surface of the first chip opposite to the first surface. The third metal pattern may be located outside the first metal pattern and the second metal pattern in the direction in which the first surface and the second surface extend. The thickness of the first chip may be measured by using the reflected light of the first metal pattern and the reflected light of the third metal pattern.

The first chip may have a first substrate, a light receiving layer, and a first electrode, the bump may be connected to the first electrode, the first transmission region may include the first substrate, and the light receiving layer and the first electrode may be provided in the region other than the first transmission region. The light transmitted through the first transmission region is reflected by the first metal pattern and the second metal pattern.

A method of manufacturing an electronic device having a first chip and a second chip. The first chip has a first transmission region, a transmittance for light of the first transmission region is higher than a transmittance of a region other than the first transmission region in the first chip, a first metal pattern is provided on a first surface that is a surface of the first chip facing the second chip, and a second metal pattern is provided on a second surface that is a surface of the second chip facing the first chip. The method includes bonding, with a bump, the first chip and the second chip arranged such that the first metal pattern and the second metal pattern overlap the first transmission region in a thickness direction of the first chip and the second chip, and such that the second metal pattern is located outside the first metal pattern in a direction in which the first surface and the second surface extend and after the bonding, making light incident on the first metal pattern and the second metal pattern through the first transmission region, and measuring a distance between the first chip and the second chip by using light reflected by the first metal pattern and light reflected by the second metal pattern. The distance between the first chip and the second chip can be measured by using the reflected light of the first metal pattern and the reflected light of the second metal pattern.

A third metal pattern may be provided on a third surface that is a surface of the first chip opposite to the first surface, and the third metal pattern may be located outside the first metal pattern and the second metal pattern in the direction in which the first surface and the second surface extend. The method of manufacturing an electronic device further includes, after the bonding, making light incident on the third metal pattern, making light incident on the first metal pattern through the first transmission region, and measuring a thickness of the first chip by using light reflected by the first metal pattern and light reflected by the third metal pattern. The thickness of the first chip can be measured.

A fourth metal pattern may be provided on a fourth surface that is a surface of the second chip opposite to the second surface, the second chip may have a second transmission region, a transmittance for light of the second transmission region may be higher than a transmittance of a region other than the second transmission region in the second chip, the fourth metal pattern may be located outside the first metal pattern and the second metal pattern in the direction in which the first surface and the second surface extend, and the bonding may be bonding the first chip and the second chip such that the second transmission region overlaps the first transmission region in the thickness direction, and such that the fourth metal pattern overlaps the first transmission region and the second transmission region. The method of manufacturing an electronic device further includes, after the bonding, making light incident on the second metal pattern through the first transmission region, making light incident on the fourth metal pattern through the first transmission region and the second transmission region, and measuring a thickness of the second chip by using light reflected by the second metal pattern and light reflected by the fourth metal pattern. The thickness of the second chip can be measured.

A method of measuring an electronic device having a first chip and a second chip. The first chip and the second chip are bonded with a bump, wherein the first chip has a first transmission region, a transmittance for light of the first transmission region is higher than a transmittance of a region other than the first transmission region in the first chip, a first metal pattern is provided on a first surface that is a surface of the first chip facing the second chip, a second metal pattern is provided on a second surface that is a surface of the second chip facing the first chip, the first metal pattern and the second metal pattern overlap the first transmission region in a thickness direction of the first chip and the second chip, and the second metal pattern is located outside the first metal pattern in a direction in which the first surface and the second surface extend. The method includes making light incident on the first metal pattern and the second metal pattern through the first transmission region and measuring a distance between the first chip and the second chip by using light reflected by the first metal pattern and light reflected by the second metal pattern. The distance between the first chip and the second chip can be measured by using the reflected light of the first metal pattern and the reflected light of the second metal pattern.

### Details of Embodiments of Present Disclosure

Specific examples of an electronic device, a method of manufacturing and a method of measuring an electronic device, according to embodiments of the present disclosure will be described below with reference to the drawings. It should be noted that the present disclosure is not limited to these examples, but is defined by the scope of claims, and is intended to include all modifications within the meaning and range equivalent to the scope of claims.

### First Embodiment

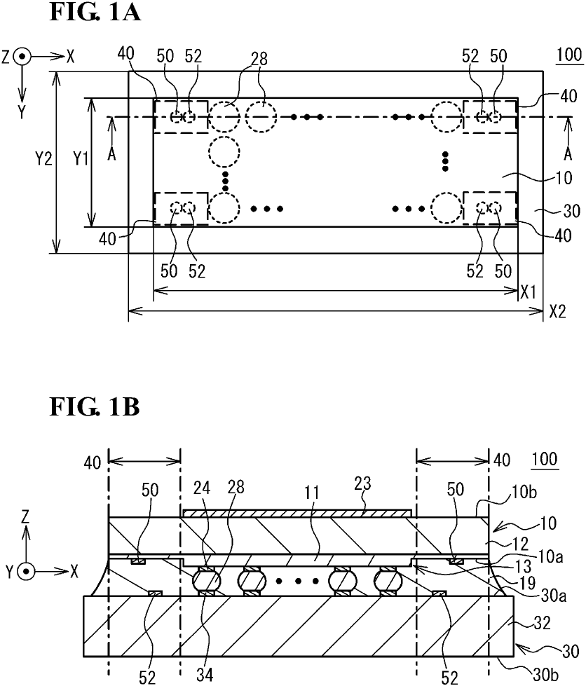

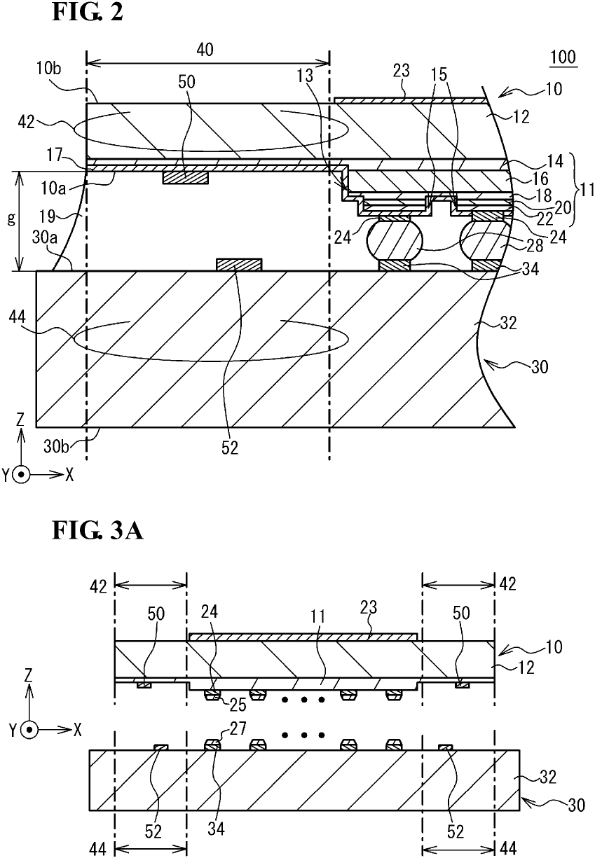

FIG. 1A is a plan view showing an electronic device 100 according to a first embodiment. FIG. 1B is a cross-sectional view taken along line A-A of FIG. 1A. FIG. 2 is an enlarged view near the transmission region.

As shown in FIG. 1A to 2, electronic device 100 is a semiconductor light-receiving device, including a sensor chip 10 (first chip) and an IC (Integrated Circuit) chip 30 (second chip). Sensor chip 10 and an IC chip 30 are bonded and electrically connected to each other by multiple bumps 28.

The Z-axis direction is the thickness direction of sensor chip 10 and IC chip 30. In the Z-axis direction, sensor chip 10 and IC chip 30 are separated from each other and face each other. An underfill 19 is filled between sensor chip 10 and IC chip 30. Underfill 19 is, for example, a resin such as epoxy.

Sensor chip 10 and IC chip 30 each have a side extending in the X-axis direction and a side extending in the Y-axis direction. The dimension Y1 of sensor chip 10 in the Y-axis direction is, for example, 4.5 mm. The dimension X1 in the X-axis direction is, for example, 10 mm. The dimension Y2 of IC chip 30 in the Y-axis direction is, for example, 7.5 mm. The dimension X2 in the X-axis direction is, for example, 12 mm. The X-axis direction, the Y-axis direction, and the Z-axis direction are orthogonal to each other.

A surface 10a (first surface) of sensor chip 10 faces IC chip 30. A surface 10b (third surface) is a surface opposite to the surface 10a of sensor chip 10. A surface 30a (second surface) of IC chip 30 faces sensor chip 10. A surface 30b (fourth surface) is a surface opposite to the surface 30a of IC chip 30. The surfaces 10a, 10b, 30a and 30b extend parallel to the XY plane. The XY plane is the direction in which the surface 10a and the surface 10b extend. A gap g is a length between the surface 10a and the surface 30a along the Z-axis direction and is, for example, 0.016 mm.

Sensor chip 10 is, for example, an FPA (Focal Plane Array) sensor. IC chip 30 is a circuit board and includes, for example, a readout integrated circuit (ROIC). Sensor chip 10 receives light such as infrared light and outputs an electric signal (current) corresponding to the intensity of the light. The electric signal is input from sensor chip 10 to IC chip 30.

As shown in FIG. 1B, sensor chip 10 includes a substrate 12 (first substrate) and a semiconductor layer 11. An antireflection coating 23 is provided on a surface (back surface) of substrate 12 opposite to semiconductor layer 11. Semiconductor layer 11 is stacked on a surface (main surface) of substrate 12 facing IC chip 30. Semiconductor layer 11 has a mesa 13 on a center part in the plane of sensor chip 10. Mesa 13 protrudes toward IC chip 30.

As shown in FIG. 2, semiconductor layer 11 includes an n-type semiconductor layer 14, a light receiving layer 16, a semiconductor layer 18, a p-type semiconductor layer 20, and a contact layer 22. N-type semiconductor layer 14, light receiving layer 16, and semiconductor layer 18 are laminated in this order from the surface of substrate 12. P-type semiconductor layer 20 and contact layer 22 are laminated on a part of the surface of semiconductor layer 18.

N-type semiconductor layer 14 is provided so as to cover the entire main surface of substrate 12. N-type semiconductor layer 14, light receiving layer 16, semiconductor layer 18, p-type semiconductor layer 20, and contact layer 22 form mesa 13. Mesa 13 includes multiple mesas 15 and multiple mesas 15 protrude toward IC chip 30. P-type semiconductor layer 20 and contact layer 22 form a mesa 15. Grooves are provided between multiple mesas 15, and multiple mesas 15 are separated from each other across these grooves. An insulating film 17 covers an upper surface and side surfaces of mesa 15, an upper surface and side surfaces of mesa 13, and a surface of n-type semiconductor layer 14. The upper surface of insulating film 17 is the surface 10a.

An electrode 24 (first electrode) is provided on a distal end surface of mesa 15. Multiple electrodes 24 include a p-type electrode and an n-type electrode. One of two electrodes 24 shown in FIG. 2 is an n-type electrode, is provided on the surface of insulating film 17, is not electrically connected to p-type semiconductor layer 20, and is electrically connected to n-type semiconductor layer 14 by a wiring (not shown). The other of two electrodes 24 shown in FIG. 2 is a p-type electrode, which is provided on the surface of contact layer 22 through the opening of insulating film 17 and is electrically connected to contact layer 22 and p-type semiconductor layer 20.

Substrate 12 and n-type semiconductor layer 14 are formed of, for example, n-type indium phosphide (n-InP). For example, silicon (Si) is used as the n-type dopant. Light receiving layer 16 is formed of, for example, indium gallium arsenide (InGaAs). Semiconductor layer 18 is formed of, for example, non-doped indium gallium arsenide phosphide (InGaAsP). P-type semiconductor layer 20 is formed of, for example, p-type indium phosphide (p-InP). Contact layer 22 is formed of, for example, p-type InGaAs. For example, zinc (Zn) is used as the p-type dopant.

The thickness of substrate 12 is, for example, 0.5 mm. The total thickness of n-type semiconductor layer 14, light receiving layer 16, semiconductor layer 18, p-type semiconductor layer 20, and contact layer 22 is smaller than the thickness of substrate 12 and is, for example, several µm. The total thickness is the thickness of semiconductor layer 11. Substrate 12 and semiconductor layer 11 may be formed of a compound semiconductor other than the above mentioned compound semiconductor.

Insulating film 17 and antireflection coating 23 are formed of, for example, silicon nitride (SiN). Electrode 24 is formed, for example, by combining multiple metals.

IC chip 30 includes a substrate 32 (second substrate) and an electrode 34 (second electrode). Multiple electrodes 34 are provided on the surface 30a. Substrate 32 is formed of, for example, silicon (Si). The thickness of substrate 32 is, for example, 0.75 mm. Electrodes 34 are formed, for example, by combining multiple metals. A bump 28 is bonded to electrode 24 and electrode 34 and electrically connects the two electrodes. Bumps 28 are formed of solder such as indium (In).

The band gaps of substrate 12, n-type semiconductor layer 14, semiconductor layer 18, p-type semiconductor layer 20, and contact layer 22 are larger than the energy of the infrared light. The band gap of light receiving layer 16 is comparable to the energy of the infrared light. Light receiving layer 16 tends to absorb infrared light, and particularly has a high absorption rate for light in the range of wavelengths from 1100 nm to 1700 nm. The infrared light is transmitted through substrate 12 and n-type semiconductor layer 14 and is absorbed by light receiving layer 16. Light receiving layer 16 absorbs infrared light and generates carriers (electrons and holes). The current generated by sensor chip 10 is read by IC chip 30, and for example, image information is generated.

As shown in FIG. 1A, electronic device 100 has four transmission regions 40. Transmission regions 40 are the portion enclosed by the dashed line in FIG. 1A. The size of transmission regions 40 in the plane are, for example, 2.4 mm×1.2 mm. Four transmission regions 40 are located near the four corners in the XY plane of sensor chip 10. Transmission region 40 includes a portion from the surface 10b to the surface 30b in the Z-axis direction. The transmittance of transmission regions 40 with respect to the infrared light is higher than the transmittance of regions other than transmission region 40. As shown in FIG. 2, transmission regions 40 include a transmission region 42 (first transmission region) and a transmission region 44 (second transmission region).

Sensor chip 10 includes transmission region 42. Transmission region 42 is located outside mesa 13 in the XY plane. Specifically, transmission region 42 is provided in a portion closer to the side edge of sensor chip 10 than mesa 13. Transmission region 42 includes substrate 12, n-type semiconductor layer 14, and insulating film 17, but does not include light receiving layer 16, semiconductor layer 18, p-type semiconductor layer 20, contact layer 22, and electrode 24. In other words, light receiving layer 16, semiconductor layer 18, p-type semiconductor layer 20, contact layer 22, and electrode 24 are provided in a region other than transmission region 42. Antireflection coating 23 is provided on the surface 10b of sensor chip 10. Antireflection coating 23 is provided in a portion overlapping mesa 13 when substrate 12 is seen through from the back surface side. Antireflection coating 23 is not provided in transmission region 42.

Transmission region 42 does not include light receiving layer 16 and electrode 24. Thus, infrared light incident on transmission region 42 is transmitted through transmission region 42 without being absorbed by light receiving layer 16 and without being absorbed and reflected by electrode 24. The transmittance of transmission region 42 with respect to infrared light is higher than the transmittance of regions other than transmission region 42 in sensor chip 10, and is, for example, 90% or more.

Metal patterns 50 (first metal pattern) are provided on the surface 10a of sensor chip 10 and are located in transmission region 42. Metal patterns 50 are formed of a metal such as Au. The thickness of metal patterns 50 is, for example, 80 nm. The planar shape of metal patterns 50 is, for example, a circle or a square. The width is, for example, 1 mm. When the planar shape of metal pattern 50 is a circle, the width means a diameter. When the planar shape of metal pattern 50 is a square, the width means the length of one side.

IC chip 30 includes transmission region 44. Transmission region 44 includes substrate 32 and does not include electrodes 34. Transmission region 44 has a portion overlapping with transmission region 42 in the Z-axis direction. To be specific, when sensor chip 10 is seen through from above the surface 10a in the Z-axis direction, there is a portion where transmission region 42 and transmission region 44 overlap each other. When seen from the Z-axis direction, transmission region 44 and transmission region 42 may overlap with each other so as to entirely coincide with each other. Alternatively, when seen from the Z-axis direction, a part of transmission region 44 and a part of transmission region 42 may overlap each other. Infrared light incident on transmission region 44 is not absorbed through transmission region 44 without being absorbed or reflected by electrodes 34. The transmittance of transmission region 44 with respect to infrared light is higher than the transmittance of regions other than transmission region 44 in IC chip 30, and is, for example, 90% or more.

A metal pattern 52 (second metal pattern) is provided on the surface 30a, is located in transmission region 44, and is located outside metal pattern 50 in the XY plane. That is, as shown in FIG. 1A, metal patterns 50 and 52 do not overlap each other in a plan view. Metal pattern 52 is formed of a metal such as Au. The thickness of metal pattern 52 is, for example, 80 nm. The planar shape of metal pattern 52 is, for example, a circle or a square. The widths are, for example, 1 mm.

When infrared light is incident on transmission region 40 from the back surface side (the upper side in FIG. 2) of sensor chip 10, the infrared light is transmitted through substrate 12 and n-type semiconductor layer 14 and is reflected by the surfaces of metal patterns 50 and 52. The distance (gap) g between sensor chip 10 and IC chip 30 can be measured by using the reflected light.

### Method of Manufacturing

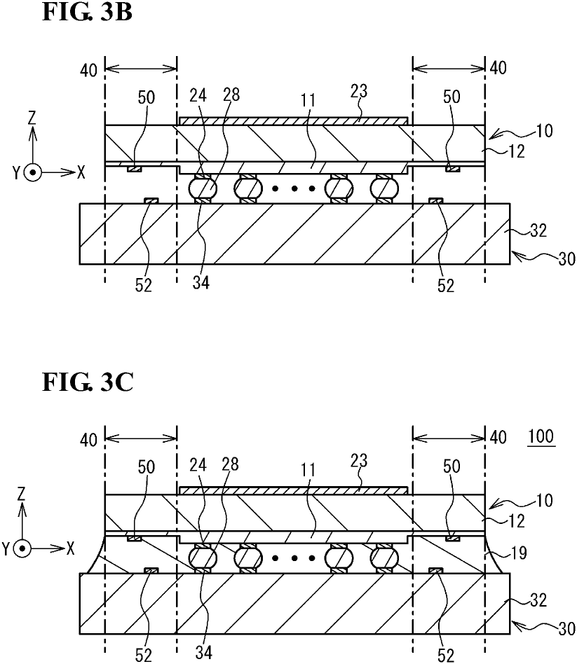

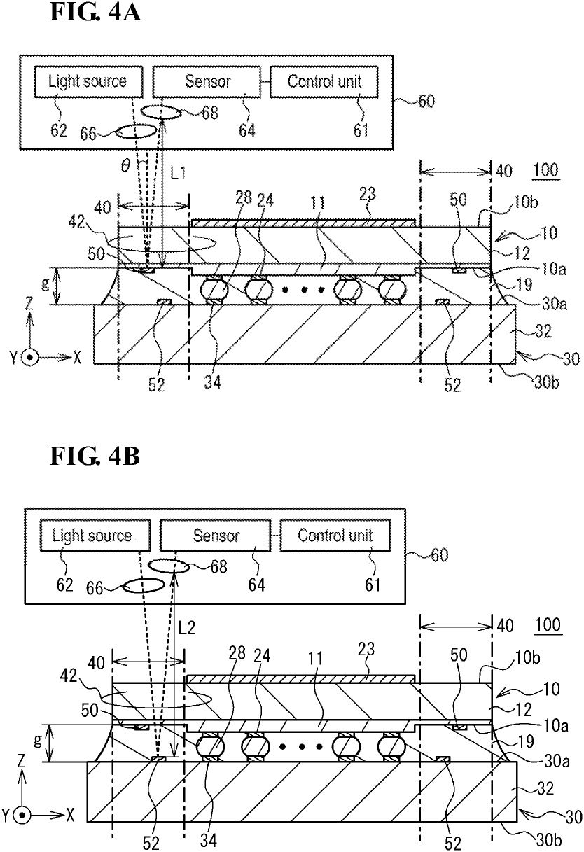

FIGS. 3A to 4B are cross-sectional views showing a method of manufacturing electronic device 100. For example, n-type semiconductor layer 14, light receiving layer 16, semiconductor layer 18, p-type semiconductor layer 20, and contact layer 22 are epitaxially grown in this order on the surface of an InP wafer (substrate 12) by metal organic chemical vapor deposition (MOCVD) or the like. Mesa 13 and mesa 15 are formed by etching or the like. Insulating film 17 and antireflection coating 23 are provided by chemical vapor deposition (CVD) or the like. Electrode 24 and metal pattern 50 are formed on a silicon wafer (substrate 32) by deposition, lift-off, or the like. The wafer is diced to form sensor chip 10 and IC chip 30.

As shown in FIG. 3A, bumps 25 are formed on electrodes 24 of sensor chip 10. Bumps 27 are formed on electrodes 34 of IC chip 30. Sensor chip 10 and IC chip 30 are aligned so that bumps 25 and bumps 27 face each other and transmission region 42 and transmission region 44 face each other. In the Z-axis direction, metal patterns 50 and 52 overlap transmission regions 42 and 44. To be specific, when sensor chip 10 is seen through from above the surface 10a (in the Z-axis direction), metal patterns 50 and 52 are located inside a portion where transmission region 42 and transmission region 44 overlap each other. In the XY plane, metal pattern 52 is located outside metal pattern 50.

As shown in FIG. 3B, a reflow process is performed to flip-chip bond sensor chip 10 and IC chip 30. Specifically, bumps 25 and 27 are brought into contact with each other and heated to a temperature equal to or higher than the melting point of the solder. Bumps 25 and bumps 27 fuse to form bumps 28. Bumps 28 are solidified, and sensor chip 10 and IC chip 30 are bonded. As shown in FIG. 3C, underfill 19 is filled between sensor chip 10 and IC chip 30.

FIGS. 4A and 4B show the steps of measuring the gap g. A measurement apparatus 60 is used for the measurement. As shown in FIGS. 4A and 4B, measurement apparatus 60 includes a control unit 61, a light source 62, a sensor 64, and lenses 66 and 68. Light source 62 is, for example, a laser light source and emits infrared light. The wavelengths of light emitted from light source 62 can be changed in a range from 900 nm to 1700 nm, for example. Sensor 64 is an array sensor including, for example, a charge coupled device (CCD) or a complementary metal oxide semiconductor (CMOS). Lenses 66 and 68 are condenser lens. Control unit 61 is a device that processes an electric signal output by sensor 64, and includes, for example, a computer and a processing circuit. Control unit 61 measures the distance to the object based on the position where sensor 64 receives the reflected light, for example, by applying triangulation. Measurement apparatus 60 may be an apparatus in which control unit 61, light source 62, sensor 64, and lenses 66 and 68 are housed in one housing.

Electronic device 100 is disposed on a movable stage (not shown). In the example of FIGS. 4A and 4B, the surface 30b is directed downwards. Light source 62 and sensor 64 are disposed above the surface 10b of sensor chip 10. Lens 66 is located between light source 62 and sensor chip 10. Lens 68 is located between sensor 64 and sensor chip 10.

Laser light is emitted from light source 62 toward electronic device 100. An angle (incident angle) θ of the emission light of light source 62 with respect to the normal direction (Z-axis direction) of the surface 10a is 0° or more and less than 90°, and is 35°, for example.

As shown in FIG. 4A, a light emitted from light source 62 is collected by lens 66, transmitted through transmission region 42 of sensor chip 10, incident on metal pattern 50, and reflected by the surface of metal pattern 50 (the interface between metal pattern 50 and insulating film 17). The reflected light from metal pattern 50 is transmitted through transmission region 42, collected by lens 68, and incident on sensor 64. Control unit 61 determines the light receiving position on sensor 64 with respect to the light reflected from metal pattern 50, and measures the distances L1 from metal pattern 50 to lens 68. After the measurement of the distances L1, electronic device 100 is moved parallel to the XY plane by a movable stage (not shown) or the like. The position of electronic device 100 in the Z-axis direction is not changed.

As shown in FIG. 4B, a light emitted from light source 62 is transmitted through transmission region 42 of sensor chip 10, incident on metal pattern 52, and reflected by the surface of metal pattern 52. The reflected light from metal pattern 52 is transmitted through transmission region 42 and incident on sensor 64. The light receiving position on sensor 64 for the reflected light of metal pattern 52 is different from the light receiving position on sensor 64 for the reflected light of metal pattern 50. Control unit 61 determines the light receiving position on sensor 64 with respect to the reflected light of metal pattern 52, and measures the distances L2 from metal pattern 52 to lens 68.

Control unit 61 calculates the distance (the gap g) between sensor chip 10 and IC chip 30 by subtracting the distance L1 from the distance L2.

As shown in FIG. 1A, four metal patterns 50 and four metal patterns 52 are provided. The measurements of FIGS. 4A and 4B are performed on four pairs of metal patterns to obtain the gap g at each position. If the gap g falls within a tolerance range, for example, 0.016 mm ± 0.005 mm, the product is a good product.

According to the first embodiment, sensor chip 10 has transmission region 42. Metal patterns 50 are provided on the surface 10a of sensor chip 10 and are located in transmission region 42. Metal patterns 52 are provided on the surface 30a of IC chip 30 and overlap transmission region 42. Transmission region 42 has a high transmittance for infrared light. The infrared light is transmitted through transmission region 42 and is irradiated to metal patterns 50 and 52. Since metal patterns 52 are located outside metal patterns 50, the infrared light is irradiated to metal patterns 52 without being blocked by metal patterns 50. The infrared light is reflected by metal patterns 50 and 52. The gap g between sensor chip 10 and IC chip 30 can be measured by using the reflected light of metal pattern 50 and the reflected light of metal patterns 52.

In the distance measurement by image recognition, an image becomes unclear due to scattering of light by substrate 12, spherical aberration, and the like, and it is difficult to perform highly accurate measurement. According to the first embodiment, the gap g is measured by using the reflected light from metal patterns 50 and the reflected light from metal patterns 52. Scattering of light and the influence of spherical aberration can be suppressed, and highly accurate measurement can be performed. Measurement apparatus 60 includes light source 62 of infrared light and sensor 64 capable of measuring a distance. Since it is not necessary to use an expensive apparatus such as a lens having high resolution, the measurement can be performed at low cost and in a simple process.

Each of sensor chip 10 and IC chip 30 is formed by dicing a wafer. When the cut surface of the dicing is rough, it is difficult to measure the gap g from the side surface. In addition, after underfill 19 is provided, it is difficult to see the side surface of sensor chip 10, and it is difficult to measure the gap g. According to the first embodiment, even after underfill 19 is filled, infrared light can be transmitted through transmission region 42, and the gap g can be measured by using reflected light from metal patterns 50 and 52.

Light receiving layer 16 and electrodes 24 are provided in a region other than transmission region 42 in sensor chip 10. Light receiving layer 16 is formed of InGaAs and has a high absorption rate for infrared light. Transmission region 42 does not include light receiving layer 16 and electrodes 24. Therefore, absorption of infrared light by light receiving layer 16, absorption and reflection by electrodes 24, and the like can be suppressed. Transmission region 42 includes substrate 12 and n-type semiconductor layer 14. Substrate 12 and n-type semiconductor layer 14 are formed of InP, and hardly absorb infrared light but transmit the infrared light. The transmittance of transmission region 42 with respect to infrared light is, for example, 80% or more, 90% or more, or the like. The transmittance depends on the wavelength of light used for measurement, and also varies depending on the thicknesses of substrate 12 and n-type semiconductor layer 14. As a specific example, as substrate 12 and n-type semiconductor layer 14 are thinner, the transmittance is higher. Light from light source 62 is transmitted through substrate 12 and n-type semiconductor layer 14 of transmission region 42, and is incident on metal patterns 50 and 52, thereby generating reflected light. Reflected light can be used to measure the gap g.

Metal patterns 50 and 52 are formed of a metal such as Au and reflect infrared light. The reflectance of metal patterns 50 and 52 with respect to infrared light is, for example, 70% or more, 80% or more, 90% or more, or the like. The higher the reflectivity, the greater the intensity of the reflected light. The reflected light should have sufficient intensity for distance measurement. In order to reflect light in an appropriate direction, the surfaces of metal patterns 50 and 52 are preferably flat. Depending on the combination of the wavelength of the light and the metal, the reflectivity and absorptivity will vary. Electrodes 24 and 34 may be formed of a multi-layer structure of multiple metals and have a high absorption rate for light. On the other hand, metal patterns 50 and 52 made of Au have a high reflectivity of 90% or more with respect to light having wavelengths ranging from 900 nm to 1700 nm, for example. Therefore, reflected light having high intensity is generated from metal patterns 50 and 52.

As shown in FIG. 1A, electronic device 100 has four transmission regions 40. Transmission region 40 is provided in the vicinity of four corners of sensor chip 10. Metal patterns 50 and 52 are provided in each of four transmission regions 40. The gap g is measured in four transmission regions 40. By comparing the four gaps g, the inclination between sensor chip 10 and IC chip 30 can be examined. In a case where sensor chip 10 is inclined with respect to IC chip 30, there is a possibility that the bonding by bumps 28 becomes defective. The four gaps g may be within a tolerance range, such as 0.016 mm ± 0.005 mm. Since sensor chip 10 and IC chip 30 are bonded to each other in a state in which sensor chip 10 and IC chip 30 are substantially parallel to each other, bonding failure is suppressed.

The number of transmission regions 42 and the number of pairs of metal patterns (metal patterns 50 and 52) may be 4 or less or may be 4 or more. In order to measure the gap g in the entire electronic device 100, it is preferable that at least four pairs of transmission region 42 and the metal pattern are provided, particularly, at four corners of sensor chip 10.

The spot size (diameter) of light emitted from light source 62 is, for example, 75 µm. The size of transmission region 40 is determined according to the spot size, the incident angle θ and the like. It is sufficient that the laser light from light source 62 is irradiated on metal patterns 50 and 52 without being blocked by light receiving layer 16, the electrodes and the like, and the reflected light from metal pattern 50 and the reflected light from metal pattern 52 are incident on sensor 64 without being blocked. The angle of incidence θ is, for example, at least 0 °. That is, light is vertically incident, and measurement is performed by using reflected light that is vertically reflected. The light may be infrared light or light other than infrared light, and may be transmitted through transmission region 40 and reflected by the metal pattern.

Measurement apparatus 60 may be disposed at a position facing the surface 30b of IC chip 30, and the infrared light may be irradiated to transmission region 44 of IC chip 30. Transmission region 44 includes substrate 32 of Si and does not include electrode 34. The infrared light is not reflected or absorbed by electrode 34, is transmitted through transmission region 44, and is reflected by metal patterns 50 and 52. The reflected light is transmitted through transmission region 44 and incident on sensor 64. The gap g is measured by using reflected light. Electronic device 100 may be a device other than a semiconductor light-receiving element.

### Second Embodiment

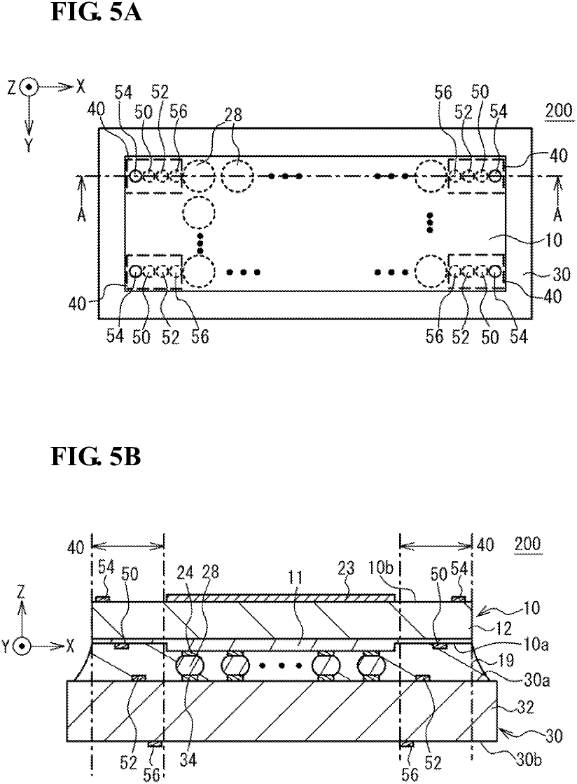

FIG. 5A is a plan view showing an electronic device 200 according to a second embodiment. FIG. 5B is a cross-sectional view taken along line A-A of FIG. 5A.

As shown in FIGS. 5A and 5B, electronic device 200 has four transmission regions 40. Metal patterns 50, 52, 54, and 56 are provided in each of the four transmission regions 40.

Metal pattern 50 is provided on the surface 10a of sensor chip 10. Metal pattern 52 is provided on the surface 30a of IC chip 30. Metal pattern 54 (third metal pattern) is provided on the surface 10b of sensor chip 10. Metal pattern 56 (fourth metal pattern) is provided on the surface 30b of IC chip 30.

Metal pattern 54, metal pattern 50, metal pattern 52, and metal pattern 56 are arranged in this order along the X-axis direction. Metal pattern 54 is located outside metal patterns 50, 52, and 56. Metal pattern 56 is located outside metal patterns 50, 52, and 54. Metal patterns 50, 52, 54, and 56 do not overlap each other. Metal patterns 50, 52, 54, and 56 are made of the same material, for example, a metal such as Au.

### Method of Manufacturing

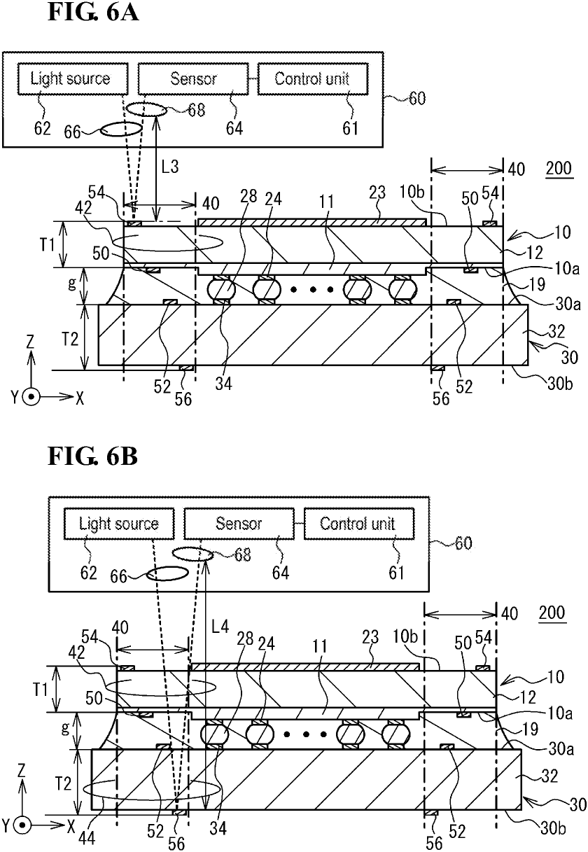

FIGS. 6A and 6B are cross-sectional views showing a method of manufacturing electronic device 200. The steps of flip-chip mounting and forming underfill 19 are the same as in the first embodiment.

As shown in FIG. 6A, measurement apparatus 60 is positioned above the surface 10b. Metal pattern 54 is irradiated with light emitted from light source 62. The reflected light generated from metal pattern 54 is incident on sensor 64. Control unit 61 determines the light receiving position on sensor 64 with respect to the reflected light of metal pattern 54, and measures the distances L3 from metal pattern 54 to lens 68.

As shown in FIG. 6B, light emitted from light source 62 is transmitted through transmission regions 42 and 44 and is irradiated onto metal pattern 56. The reflected light generated from metal pattern 56 is transmitted through transmission regions 42 and 44, and incident on sensor 64. Control unit 61 determines the light receiving position on sensor 64 with respect to the reflected light of metal pattern 56, and measures the distances L4 from metal pattern 56 to lens 68.

As in the step of FIG. 4A, metal pattern 50 is irradiated with infrared light, and the reflected light is received by sensor 64. As in the step of FIG. 4B, metal pattern 52 is irradiated with infrared light, and the reflected light is received by sensor 64. The distances L1 and L2 are measured.

Control unit 61 calculates the thicknesses T1 of sensor chip 10 by subtracting the distance L3 from the distance L1. Control unit 61 calculates the thicknesses T2 of IC chips 30 by subtracting the distances L2 from the distances L4.

According to the second embodiment, metal pattern 50 is provided on the surface 10a of sensor chip 10 and is located in transmission region 42. Metal pattern 54 is provided on the surface 10b. Metal pattern 52 is provided on the surface 30a of IC chip 30 and overlaps transmission region 42. Metal pattern 56 is provided on the surface 30b and overlaps transmission regions 42 and 44. The infrared light is reflected by metal pattern 54. The infrared light transmitted through transmission region 42 is reflected by metal pattern 50. The thicknesses T1 of sensor chip 10 can be measured by using the reflected light from metal pattern 54 and the reflected light from metal pattern 50.

The infrared light transmitted through transmission region 42 is reflected by metal pattern 52. The light transmitted through transmission regions 42 and 44 is reflected by metal pattern 56. The thicknesses T2 of IC chip 30 can be measured by using the reflected light from metal pattern 52 and the reflected light from metal pattern 56. According to the second embodiment, the thicknesses T1 and T2 can be measured as well as the gap g.

The gap g and the thicknesses T1 and T2 can be measured by a simple process by using a low-cost measurement apparatus 60. The measurement accuracy of the second embodiment is higher than the measurement by image recognition. The measurement is possible even after underfill 19 is filled.

It is preferable to measure the gap g and the thicknesses T1 and T2 in each of four transmission regions 40. At multiple positions of electronic device 100, it can be checked whether the gap g, the thicknesses T1 and T2 are within a tolerance range.

Measurement apparatus 60 may be disposed at a position facing the surface 30b of IC chip 30, and the infrared light may be irradiated to transmission region 44 of IC chip 30. The infrared light is reflected by metal pattern 56. The infrared light is transmitted through transmission region 44 and is reflected by metal patterns 50 and 52. The reflected light is transmitted through transmission region 44 and incident on sensor 64. The infrared light is transmitted through transmission regions 44 and 42 and is reflected by metal pattern 54. The reflected light is transmitted through transmission regions 44 and 42 and is incident on sensor 64. The gap g, thicknesses T1 and T2 are measured by using reflected light.

In the example of FIG. 5A, both metal pattern 54 and metal pattern 56 are located in transmission region 40. Light may be irradiated from either sensor chip 10 side or IC chip 30 side. Either metal pattern 54 or metal pattern 56 may be located in transmission region 40. For example, when metal pattern 54 is located outside transmission region 40 and metal pattern 56 is located in transmission region 40, light is irradiated from sensor chip 10 side. The light is reflected by metal pattern 54. The light transmitted through transmission region 40 is reflected by metal pattern 56. At least one of metal patterns 54 and 56 may overlap transmission regions 42 and 44.

Although the embodiments of the present disclosure have been described in detail, the present disclosure is not limited to the specific embodiments, and various modifications and changes can be made within the scope of the present disclosure described in the claims.

What is claimed is:

1. An electronic device comprising:
a first chip;
a second chip bonded to the first chip with a bump;
a first metal pattern provided on a first surface that is a surface of the first chip facing the second chip; and
a second metal pattern provided on a second surface that is a surface of the second chip facing the first chip,
wherein the first chip has a first transmission region,
wherein a transmittance for light of the first transmission region is higher than a transmittance of a region other than the first transmission region in the first chip,
wherein the first metal pattern and the second metal pattern overlap the first transmission region in a thickness direction of the first chip and the second chip, and
wherein the second metal pattern is located outside the first metal pattern in a direction in which the first surface and the second surface extend.

2. The electronic device according to claim 1,
wherein the second chip has a second transmission region,
wherein a transmittance for light of the second transmission region is higher than a transmittance of a region other than the second transmission region in the second chip,
wherein the second transmission region overlaps the first transmission region in the thickness direction, and
wherein the first metal pattern and the second metal pattern overlap the first transmission region and the second transmission region in the thickness direction of the first chip and the second chip.

3. The electronic device according to claim 2, comprising:
a fourth metal pattern provided on a fourth surface that is a surface of the second chip opposite to the second surface,
wherein the fourth metal pattern is located outside the first metal pattern and the second metal pattern in the direction in which the first surface and the second surface extend.

4. The electronic device according to claim 2,
wherein the second chip has a second substrate and a second electrode,
wherein the bump is connected to the second electrode,
wherein the second transmission region includes the second substrate, and
wherein the second electrode is provided in the region other than the second transmission region.

5. The electronic device according to claim 1,
wherein the first chip has the first transmission region including multiple first transmission regions, and the first metal pattern including multiple first metal patterns, and
wherein the second chip has the second metal pattern including multiple second metal patterns.

6. The electronic device according to claim 1, comprising:
a third metal pattern provided on a third surface that is a surface of the first chip opposite to the first surface,
wherein the third metal pattern is located outside the first metal pattern and the second metal pattern in the direction in which the first surface and the second surface extend.

7. The electronic device according to claim 1,
wherein the first chip has a first substrate, a light receiving layer, and a first electrode,
wherein the bump is connected to the first electrode,
wherein the first transmission region includes the first substrate, and
wherein the light receiving layer and the first electrode are provided in the region other than the first transmission region.

8. A method of manufacturing an electronic device having a first chip and a second chip, wherein the first chip has a first transmission region,
wherein a transmittance for light of the first transmission region is higher than a transmittance of a region other than the first transmission region in the first chip,
wherein a first metal pattern is provided on a first surface that is a surface of the first chip facing the second chip, and
wherein a second metal pattern is provided on a second surface that is a surface of the second chip facing the first chip,
the method comprising:
bonding, with a bump, the first chip and the second chip arranged such that the first metal pattern and the second metal pattern overlap the first transmission region in a thickness direction of the first chip and the second chip, and such that the second metal pattern is located outside the first metal pattern in a direction in which the first surface and the second surface extend; and
after the bonding, making light incident on the first metal pattern and the second metal pattern through the first transmission region, and measuring a distance between the first chip and the second chip by using light reflected by the first metal pattern and light reflected by the second metal pattern.

9. The method of manufacturing an electronic device according to claim 8,
wherein a third metal pattern is provided on a third surface that is a surface of the first chip opposite to the first surface, and
wherein the third metal pattern is located outside the first metal pattern and the second metal pattern in the direction in which the first surface and the second surface extend,
the method further comprising:
after the bonding, making light incident on the third metal pattern, making light incident on the first metal pattern through the first transmission region, and measuring a thickness of the first chip by using light reflected by the first metal pattern and light reflected by the third metal pattern.

10. The method of manufacturing an electronic device according to claim 8,
wherein a fourth metal pattern is provided on a fourth surface that is a surface of the second chip opposite to the second surface,
wherein the second chip has a second transmission region,
wherein a transmittance for light of the second transmission region is higher than a transmittance of a region other than the second transmission region in the second chip,
wherein the fourth metal pattern is located outside the first metal pattern and the second metal pattern in the direction in which the first surface and the second surface extend, and
wherein the bonding is bonding the first chip and the second chip such that the second transmission region overlaps the first transmission region in the thickness direction, and such that the fourth metal pattern overlaps the first transmission region and the second transmission region,
the method further comprising:
after the bonding, making light incident on the second metal pattern through the first transmission region, making light incident on the fourth metal pattern through the first transmission region and the second transmission region, and measuring a thickness of the second chip by using light reflected by the second metal pattern and light reflected by the fourth metal pattern.

11. A method of measuring an electronic device having a first chip and a second chip,
wherein the first chip and the second chip are bonded with a bump,
wherein the first chip has a first transmission region,
wherein a transmittance for light of the first transmission region is higher than a transmittance of a region other than the first transmission region in the first chip,
wherein a first metal pattern is provided on a first surface that is a surface of the first chip facing the second chip,
wherein a second metal pattern is provided on a second surface that is a surface of the second chip facing the first chip,
wherein the first metal pattern and the second metal pattern overlap the first transmission region in a thickness direction of the first chip and the second chip, and
wherein the second metal pattern is located outside the first metal pattern in a direction in which the first surface and the second surface extend,
the method comprising:
making light incident on the first metal pattern and the second metal pattern through the first transmission region; and
measuring a distance between the first chip and the second chip by using light reflected by the first metal pattern and light reflected by the second metal pattern.
